(19) United States
(12) Patent Application Publication
(10) Pub. No.: US 2021/0208605 A1
(43) Pub. Date: Jul. 8, 2021

(54) DATA PROCESSING METHOD AND DEVICE, AND UNMANNED AERIAL VEHICLE

(71) Applicant: SZ DJI TECHNOLOGY CO., LTD., Shenzhen (CN)

(72) Inventors: Junping MA, Shenzhen (CN); Qiang ZHANG, Shenzhen (CN); Zisheng CAO, Shenzhen (CN); Kang YANG, Shenzhen (CN)

(21) Appl. No.: 17/211,136

(22) Filed: Mar. 24, 2021

Related U.S. Application Data
(63) Continuation of application No. PCT/CN2018/108401, filed on Sep. 28, 2018.

(51) Int. Cl. G05D 1/10; G06N 3/08; B64C 39/02; B64D 47/08; G06K 9/62; H04N 7/18; G10L 25/30; G10L 25/48

(52) U.S. Cl. CPC G05D 1/101; G06N 3/08; B64C 39/024; B64D 47/08; H03M 7/30; H04N 7/185; G10L 25/30; G10L 25/48; G06K 9/6256

(57) ABSTRACT

A data processing method includes reading compressed a neural network parameter for a neural network from a memory, decompressing the compressed neural network parameter to generate a decompressed neural network parameter, and processing target data according to the decompressed neural network parameter.

### CROSS-REFERENCE TO RELATED APPLICATION

This application is a continuation of International Application No. PCT/CN2018/108401, filed Sep. 28, 2018, the entire content of which is incorporated herein by reference.

### TECHNICAL FIELD

The present disclosure relates to the field of data processing and, in particularly, to a data processing method, device, and unmanned aerial vehicle.

### BACKGROUND

With the development of microelectronics technology, computing power of hardware systems has been greatly improved. Artificial intelligence technology has once again become a research focus. As the basis of artificial intelligence, artificial neural networks have good application prospects in the fields of information, engineering, and economics, especially in aspects of image recognition, speech recognition, and etc. Taking the image recognition application as an example, the current hardware platform executing artificial neural networks includes an operating resource and a storage system. The storage system stores parameters of the artificial neural network and an image to be recognized. When the image is recognized, the parameters of the artificial neural network and the image to be recognized stored in the storage system are read by the operating resources via a bus, and a convolution operation is performed based on the parameters of the artificial neural network and the image to be recognized. The convolution operation often requires multiple iterations and frequent reading of the storage system, thereby occupying very high storage system band.

### SUMMARY

In accordance with the disclosure, there is provided a data processing method including reading compressed a neural network parameter for a neutral network from a memory, decompressing the compressed neural network parameter to generate a decompressed neural network parameter, and processing target data according to the decompressed neural network parameter.

Also in accordance with the disclosure, there is provided a data processing device including a memory, and a processor connected to the memory via a communication bus and used to read a compressed neural network parameter for a neutral network from the memory, to decompress the compressed neural network parameter to generate a decompressed neural network parameter, and to process target data according to the decompressed neural network parameter.

Also in accordance with the disclosure, there is provided an unmanned aerial vehicle including a frame, a gimbal, and an image device connected to the frame via the gimbal. The frame includes a plurality of vehicle arms each used to carry a motor and a propeller, a memory, and a processor connected to the memory via a communication bus. The propeller is used to drive the unmanned aerial vehicle to fly under the action of the motor. The processor is used to read a compressed neural network parameter from the memory, decompress the compressed neural network parameter to generate a decompressed neural network parameter, and process target data according to the decompressed neural network parameter.

### BRIEF DESCRIPTION OF THE DRAWINGS

FIG. 1 is a schematic structural diagram of an example unmanned aerial system.

FIG. 2 is a schematic flow chart of a data processing method according to an example embodiment.

FIG. 3 is a schematic diagram showing a process for obtaining compressed neural network parameters according to an example embodiment.

FIG. 4 is a schematic diagram showing a convolution operation according to an example embodiment.

FIG. 5 is a schematic diagram showing data processing according to an example embodiment.

FIG. 6 is a schematic diagram showing data processing according to another example embodiment.

FIG. 7 is a schematic structural diagram of a data processing device according to an example embodiment.

FIG. 8 is a schematic structural diagram of an unmanned aerial vehicle according to an example embodiment.

### DETAILED DESCRIPTION OF THE EMBODIMENTS

To make the objectives, technical solutions, and advantages of the embodiments of the present disclosure clearer, the technical solutions of the present disclosure will be described with reference to the drawings. It will be appreciated that the described embodiments are some rather than all of the embodiments of the present disclosure. Other embodiments conceived by those having ordinary skills in the art on the basis of the described embodiments without inventive efforts should fall within the scope of the present disclosure.

The embodiments of the present disclosure provide a data processing method, device, and unmanned aerial vehicle. The unmanned aerial vehicle may be, for example, a rotorcraft, e.g., a multi-rotor aircraft propelled by a plurality of propulsion devices through the air, and the embodiments of the present disclosure are not limited thereto.

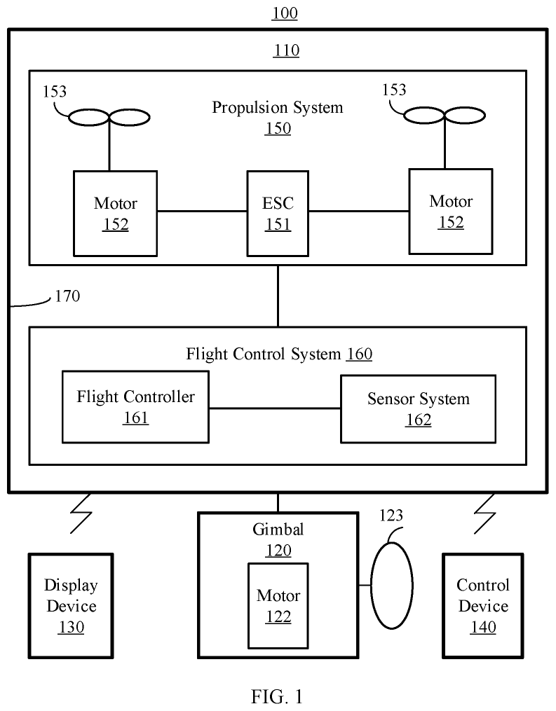

FIG. 1 is a schematic structural diagram of an example unmanned aerial system 100. A rotor unmanned aerial vehicle is taken as an example for description.

The unmanned aerial system 100 includes an unmanned aerial vehicle (UAV) 110, a gimbal 120, a display device 130, and a control device 140. The UAV 110 includes a propulsion system 150, a flight control system 160, and a frame. The UAV 110 may wirelessly communicate with the control device 140 and the display device 130.

The frame may include a vehicle body and a stand (also called a landing gear). The vehicle body may include a central frame, one or more vehicle arms connected to the central frame, and the one or more vehicle arms extend radially from the central frame. The stand is connected to the vehicle body and used to support the UAV 110 for landing.

The power system 150 includes one or more electronic speed controllers (ESCs) 151, one or more propellers 153, and one or more motors 152 corresponding to the one or more propellers 153, where the motors 152 are connected between the electronic speed controller 151 and the propeller 153, and the motor 152 and the propeller 153 are arranged at the vehicle arm of the UAV 110. The electronic speed controller 151 is used to receive the driving signal generated by the flight control system 160, and supply driving current to the motor 152 to control the speed of the motor 152 according to the driving signal. The motor 152 is used to drive the propeller to rotate, thereby providing power for the flight of the UAV 110, which enables the UAV 110 to achieve one or more degrees of freedom of movement. In some embodiments, UAV 110 may rotate around one or more rotation axes. For example, the rotation axis may include a roll axis, a yaw axis, and a pitch axis. The motor 152 may be a direct current (DC) motor or an alternating current (AC) motor. In addition, the motor 152 may be a brushless motor or a brushed motor.

The flight control system 160 includes a flight controller 161 and a sensor system 162. The sensor system 162 is used to measure attitude information of the UAV, that is, the position information and status information of the UAV 110 in space, such as three-dimensional position, three-dimensional angle, three-dimensional velocity, three-dimensional acceleration, and three-dimensional angular velocity, etc. The sensor system 162 may include, for example, at least one of sensors such as a gyroscope, an ultrasonic sensor, an electronic compass, an inertial measurement unit (IMU), a vision sensor, a global navigation satellite system, and a barometer. For example, the global navigation satellite system may be the global positioning system (GPS). The flight controller 161 is used to control the flight of the UAV 110. For example, the flight of the UAV 110 may be controlled according to the attitude information measured by the sensor system 162. The flight controller 161 may control the UAV 110 according to pre-programmed program instructions and may control the UAV 110 by responding to one or more control instructions from the control device 140.

The gimbal 120 includes a motor 122 and is used to carry an image device 123 or a microphone (not shown). The flight controller 161 may control the movement of the gimbal 120 via the motor 122. For example, in an example embodiment, the gimbal 120 may further include a controller to control the movement of the gimbal 120 by controlling the motor 122. The gimbal 120 may be separated from the UAV 110 or be a part of the UAV 110. The motor 122 may be a DC motor or an AC motor. In addition, the motor 122 may be a brushless motor or a brushed motor. The gimbal 120 may be located at the top of the UAV or at the bottom of the UAV.

The image device 123 may be, for example, a device for capturing images, such as a camera or a video camera. The image device 123 may communicate with the flight controller and shoot under the control of the flight controller. The image device 123 may include at least a photosensitive element, and the photosensitive element is, for example, a complementary metal oxide semiconductor (CMOS) sensor or a charge-coupled device (CCD) sensor.

The display device 130 is located at the ground terminal of the UAV 100, may communicate with the UAV 110 in a wireless manner, and may be used to display the attitude information of the UAV 110. In addition, the image shot by the image device may also be displayed on the display device 130. The display device 130 may be a separate device or integrated in the control device 140.

The control device 140 is located at the ground terminal of the UAV 100 and may communicate with the UAV 110 in a wireless manner for remote control of the UAV 110.

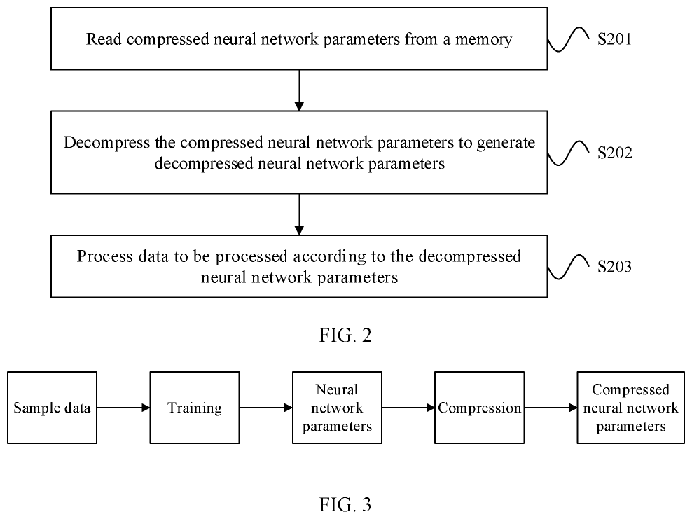

FIG. 2 is a schematic flow chart of a data processing method according to an example embodiment. The data processing method may be applied to an electronic device, such as a UAV, a mobile phone, a tablet, a digital camera, a personal computer, and etc. The UAV is taken as an example electronic device for description below.

As shown in FIG. 2, at S201, compressed neural network parameters are read from a memory.

At 202, the compressed neural network parameters are decompressed to generate decompressed neural network parameters.

At S203, data to be processed is processed according to the decompressed neural network parameters. The data to be processed is also referred to as “target data.”

The compressed neural network parameters are stored in the memory of the UAV. When the UAV processes the data to be processed, the UAV reads the compressed neural network parameters from the memory. Because the obtained neural network parameters are compressed, the UAV also needs to decompress the compressed neural network parameters. The neural network parameters are decompressed to generate the decompressed neural network parameters. Then the UAV processes the data to be processed according to the decompressed neural network parameters.

A neural network may be a convolutional neural network, a cyclic neural network, or a deep neural network, which is not restricted in the present disclosure.

For example, the neural network parameters may include weights and offsets of the neural network, which are not restricted in the present disclosure.

For example, a size of the neural network parameters before compression is 100 MB, and the size of the compressed neural network parameters is 60 MB, which may save a storage space of 40 MB. Assuming that the neural network parameters are read from the memory 30 times per second, the band occupied by obtaining the neural network parameters from the memory before compression is 100 MB×8×30=24 Gbps, the band occupied by obtaining the compressed neural network parameters from the memory is 60 MB×8×30=14.4 Gbps, which may save nearly 10 Gbps of band.

For example, the data to be processed may be image data or may be audio data. Taking a UAV as an example, the image data may be captured by an image device on the UAV, and the audio data may be captured by a microphone on the UAV.

In an example embodiment, the compressed neural network parameters are read from the memory, the compressed neural network parameters are decompressed, and then the data to be processed is processed according to the decompressed neural network parameters. Because the neural network parameters are stored in the memory in a compressed form, the storage space occupied by the neural network parameters is reduced, the access pressure of the memory is reduced, and the band occupied by reading the memory is reduced.

FIG. 3 is a schematic diagram showing a process for obtaining compressed neural network parameters according to an example embodiment. As shown in FIG. 3, before executing the above-described solution, the UAV also obtains sample data, performs training based on the sample data to obtain neural network parameters, then compresses the neural network parameters to obtain the compressed neural network parameters, and then write the compressed neural network parameters into the memory.

For example, a large number of samples may be obtained, and neural network parameters may be obtained by training based on a large amount of sample data. The neural network parameters may be used for image recognition, for example, to distinguish animals such as cats, dogs, cows, sheep, and etc. To obtain the neural network parameters, a large number of image data of animals such as cats, dogs, cows, sheep, and etc. need to be obtained, and the image data of animals such as cats, dogs, cows, sheep, and etc. is used in training to obtain the neural network parameters. Correspondingly, a result of the data processing obtained by process S203 is, for example, identifying an animal as a cat, dog, cow, sheep, or other animal.

Obtaining sample data and performing training to obtain neural network parameters based on the sample data may also be implemented by an electronic device (e.g., a server, a personal computer, etc.) other than UAV. Then the UAV obtains the neural network parameters from the electronic device, compresses the neural network parameters to obtain the compressed neural network parameters, and writes the compressed neural network parameters into the memory. The data volume of the neural network parameters obtained by training may range from a few KB to hundreds of MB.

In some embodiments, a possible implementation manner for UAV to compress the neural network parameters and obtain the compressed neural network parameters is using a lossless compression algorithm to compress the neural network parameters and obtain the compressed neural network parameters. The lossless compression algorithm may be, for example, Huffman coding or an arithmetic coding compression algorithm. The lossless compression algorithm may ensure that the compressed neural network parameters are not lost, and the neural network parameters after decompression are exactly the same as those before compression.

In some embodiments, another possible implementation manner for UAV to compress the neural network parameters and obtain the compressed neural network parameters the UAV is using a lossy compression algorithm with a compression rate greater than a preset compression rate to compress the neural network parameters and obtain the compressed neural network parameters. The preset compression rate is determined according to an actual application scenario. A compression algorithm with a greater compression rate may reduce the data volume and the storage space occupied by the compressed neural network parameters as much as possible.

In some embodiments, when the neural network is a convolutional neural network, a possible implementation of process S203 is performing convolution operation and pooling operation on the data to be processed according to the decompressed neural network parameters.

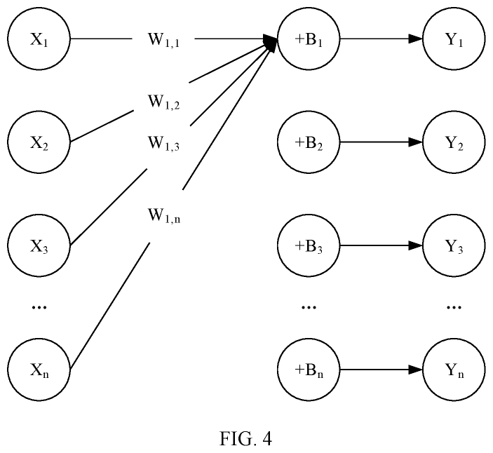

FIG. 4 is a schematic diagram showing a convolution operation according to an example embodiment. For example, the neural network parameters include weights and offsets of the neural network, and the data to be processed is image data.

As shown in FIG. 4, X₀˜Xₙ are all pixels in the image data, each pixel is multiplied by a corresponding weight W_{1,i} and the multiplication results are summed, and an offset B₁ is added to the resulting sum to obtain Y₁. Similarly, each pixel is multiplied by another corresponding weight W_{2,i} and the multiplication results are summed, and an offset B₂ is added to the resulting sum to obtain Y₂. The above process is repeated similarly for other sets of weights and offsets. The above-described calculation process may also be expressed as formula (1):

$${Y}_{k} = {\sum }_{i = 1}^{n} {X}_{i} * {W}_{k , i} + {B}_{k} \qquad ( 1 )$$

The above-described calculation process may need to be iterated many times. Y₀₁˜Yₙ₁ are obtained from X₀˜Xₙ via formula (1), which is the first iteration process. Then Y₀₁˜Yₙ₁ are taken as X₀˜Xₙ to calculate Y₀₂˜Yₙ₂ by formula (1), which is the second iteration process, and so on.

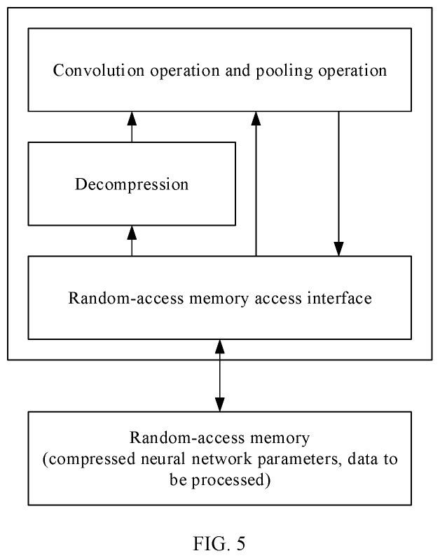

In some embodiments, the data to be processed and the compressed neural network parameters are stored in the same memory, such as a random-access memory or a flash memory. FIG. 5 is a schematic diagram showing data processing according to an example embodiment. As shown in FIG. 5, the random-access memory is taken as an example, the neural network parameters obtained by training are compressed and stored in the random-access memory, and the data to be processed is also stored in the random-access memory. Therefore, in an example embodiment, the compressed neural network parameters and the data to be processed are read from the memory. The compressed neural network parameters are decompressed to generate the decompressed neural network parameters. Then the data to be processed are processed according to the decompressed neural network parameters, where convolution operation and pooling operation are taken as an example in FIG. 5, which are not restricted in the present disclosure. Because the data volume of compressed neural network parameters is small, the occupied memory space is reduced, and the memory band occupied by reading the compressed neural network parameters from the memory each time may be reduced to improve the system operating performance.

For example, after the data to be processed is processed according to the decompressed neural network parameters to obtain a result of the data processing, the result of data processing is also written into the memory.

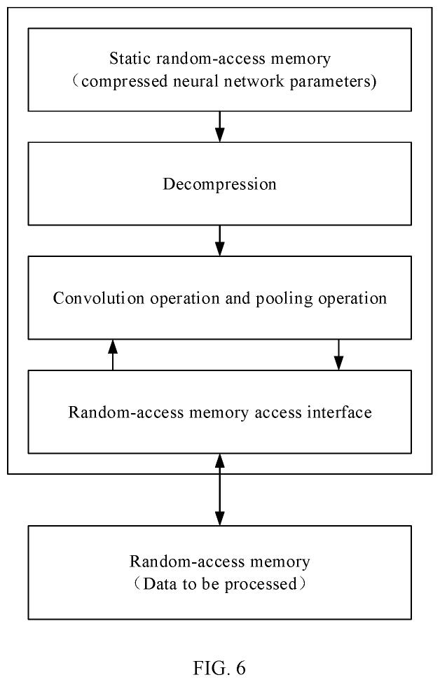

In some embodiments, the data to be processed and the compressed neural network parameters are stored in different memories. FIG. 6 is a schematic diagram showing data processing according to another example embodiment. As shown in FIG. 6, in an example embodiment, the neural network parameters obtained by training are compressed and stored in a static random-access memory (SRAM), and the data to be processed is stored in the random-access memory. Therefore, the compressed neural network parameters are read from the SRAM, and the data to be processed is read from the random-access memory. The compressed neural network parameters are decompressed to generate the decompressed neural network parameters. Then the data to be processed are processed according to the decompressed neural network parameters. Because the data volume of the compressed neural network parameters is small, the space occupied by the SRAM is reduced.

A computer storage medium storing program instructions is provided in the embodiments of the present disclosure. The program instructions may be executed to perform some or all of the processes of the data processing method in the above-described embodiments.

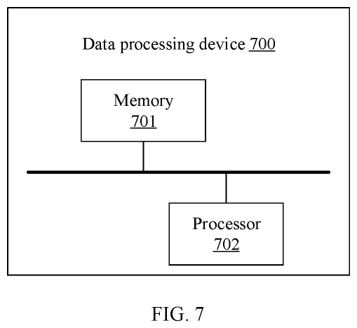

FIG. 7 is a schematic structural diagram of a data processing device 700 according to an example embodiment. The data processing device 700 includes a memory 701 storing compressed neural network parameters and a processor 702 connected to the memory 701 via a communication bus.

The processor 702 is used to read compressed neural network parameters from the memory 701, to decompress the compressed neural network parameters to generate decompressed neural network parameters, and to process data to be processed according to the decompressed neural network parameters. The data to be processed is also referred to as “target data.”

In some embodiments, the processor 702 is further used to obtain sample data before reading the compressed neural network parameters from the memory 701, to perform training based on the sample data to obtain the neural network parameters, to compress the neural network parameters to obtain the compressed neural network parameters, and to write the compressed neural network parameters into the memory 701.

In some embodiments, the processor 702 is specifically used to compress the neural network parameters using a lossless compression algorithm to obtain the compressed neural network parameters.

In some embodiments, the processor 702 is specifically used to compress the neural network parameters using a lossy compression algorithm with a compression rate greater than a preset compression rate to obtain the compressed neural network parameters.

In some embodiments, a neural network includes a convolutional neural network.

The processor 702 is specifically used to perform a convolution operation and a pooling operation on the data to be processed according to the decompressed neural network parameters.

In some embodiments, the neural network parameters include weights and offsets of the neural network.

In some embodiments, the processor 702 is further used to read the data to be processed from the memory 701 before processing the data to be processed according to the decompressed neural network parameters.

In some embodiments, the processor 702 is further configured to write a result of processing the data to be processed into the memory 701 after processing the data to be processed according to the decompressed neural network parameters.

In some embodiments, the memory 701 includes a static random-access memory.

In some embodiments, the memory 701 includes a random-access memory or a flash memory.

In some embodiments, the data to be processed includes image data or audio data.

The data processing device may be used to implement the technical solutions of the above-described data processing method consistent with the embodiments of the present disclosure, and implementation principles and technical effects are similar, which are omitted here.

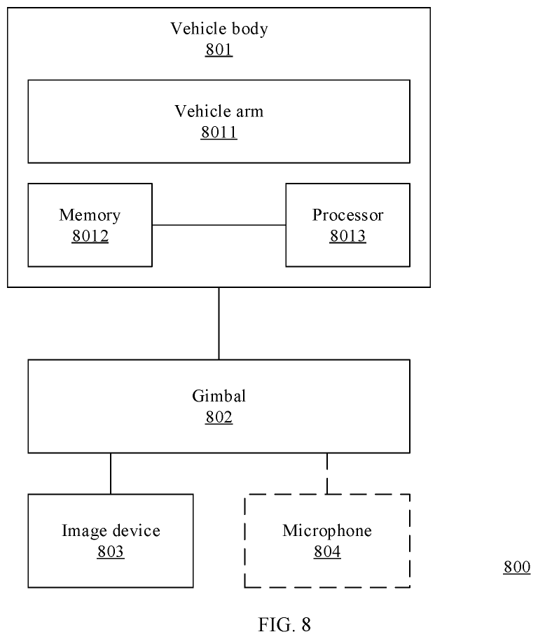

FIG. 8 is a schematic structural diagram of an unmanned aerial vehicle 800 according to an example embodiment. The unmanned aerial vehicle 800 includes a vehicle body 801, a gimbal 802, and an image device 803. The imaging device 803 is connected to the vehicle body 801 via the gimbal 802. The vehicle body 801 includes a plurality of vehicle arms 8011, and each arm 8011 is used to carry a motor and a propeller. The propeller is used to drive the UAV 800 to fly under the action of the motor. The motor and the propeller are not shown in FIG. 8, which may be refer to those shown in FIG. 1.

The body 801 includes a memory 8012 and a processor 8013, and the memory 8012 and the processor 8013 are connected via a communication bus.

The processor 8013 is used to read compressed neural network parameters from the memory 8012, to decompress the compressed neural network parameters to generate decompressed neural network parameters, and to process image data captured by the image device 803 according to the decompressed neural network parameters.

In some embodiments, the processor 8013 is further used to obtain sample data before reading the compressed neural network parameters from the memory 8012, to perform training according to the sample data to obtain neural network parameters, to compress the neural network parameters to obtain the compressed neural network parameters, and to write the compressed neural network parameters into the memory 8012.

In some embodiments, the processor 8013 is specifically used to compress the neural network parameters using a lossless compression algorithm to obtain the compressed neural network parameters.

In some embodiments, the processor 8013 is specifically used to compress the neural network parameters using a lossy compression algorithm with a compression rate greater than a preset compression rate to obtain the compressed neural network parameters.

In some embodiments, a neural network includes a convolutional neural network.

The processor 8013 is specifically used to perform a convolution operation and a pooling operation on data to be processed according to the decompressed neural network parameters.

In some embodiments, the neural network parameters include weights and offsets of the neural network.

In some embodiments, the processor 8013 is further used to read the data to be processed from the memory 8012 before processing the data to be processed according to the decompressed neural network parameters.

In some embodiments, the processor 8013 is further used to write a result of processing the data to be processed into the memory 8012 after processing the data to be processed according to the decompressed neural network parameters.

In some embodiments, the memory 8012 includes a static random-access memory.

In some embodiments, the memory 8012 includes a random-access memory or a flash memory.

In some embodiments, the UAV 800 further includes a microphone 804, which is mounted at the body 801.

The processor 8013 is further used to process the audio data collected by the microphone 804 according to the decompressed neural network parameters.

For example, the microphone 804 may be mounted at the vehicle body 801 via the gimbal 802, or directly mounted at the vehicle body 801 without using the gimbal 802.

The UAV 800 may be used to implement the technical solutions of the above-described data processing method consistent with the embodiments of the disclosure, and implementation principles and technical effects are similar, which are omitted here.

Some or all of the processes in the above-described method consistent with the disclosure may be implemented by a computer program instructing relevant hardware. The program may be stored in a computer-readable storage medium. When the program is executed, the process in the above-described method consistent with the disclosure is executed. The storage medium can be any medium that can store program codes, for example, a read-only memory (ROM), a random-access memory (RAM), a magnetic disk, or an optical disk.

Other embodiments of the disclosure will be apparent to those skilled in the art from consideration of the specification and practice of the embodiments disclosed herein. It is intended that the specification and examples be considered as example only and not to limit the scope of the disclosure, with a true scope and spirit of the invention being indicated by the following claims.

What is claimed is:

1. A data processing method comprising:
reading a compressed neural network parameter for a neural network from a memory;
decompressing the compressed neural network parameter to generate a decompressed neural network parameter; and
processing target data to be processed according to the decompressed neural network parameter.

2. The method of claim 1, further comprising, before reading the compressed neural network parameter from the memory:
obtaining sample data;
performing training according to the sample data to obtain a neural network parameter;
compressing the neural network parameter to obtain the compressed neural network parameter; and
writing the compressed neural network parameter into the memory.

3. The method of claim 2, wherein compressing the neural network parameter to obtain the compressed neural network parameter includes:
compressing the neural network parameter using a lossless compression algorithm to obtain the compressed neural network parameter.

4. The method of claim 2, wherein compressing the neural network parameter to obtain the compressed neural network parameter includes:
compressing the neural network parameter using a lossy compression algorithm with a compression rate greater than a preset compression rate to obtain the compressed neural network parameter.

5. The method of claim 1, wherein:
the neural network includes a convolutional neural network; and
processing the target data according to the decompressed neural network parameter includes:
performing a convolution operation and a pooling operation on the target data according to the decompressed neural network parameter.

6. The method of claim 1, wherein the neural network parameter includes a weight and an offset of the neural network.

7. The method of claim 1, further comprising, before processing the target data according to the decompressed neural network parameter:
reading the target data from the memory.

8. The method of claim 7, further comprising, after processing the target according to the decompressed neural network parameter:
writing a result of processing the target data into the memory.

9. The method of claim 1, wherein the memory includes a static random-access memory.

10. The method of claim 1, wherein the memory includes a random-access memory or a flash memory.

11. The method of claim 1, wherein the target data includes image data or audio data.

12. A data processing device comprising:
a memory; and
a processor connected to the memory via a communication bus and configured to:
read a compressed neural network parameter from the memory;
decompress the compressed neural network parameter to generate a decompressed neural network parameter; and
process target data to be processed according to the decompressed neural network parameter.

13. The device of claim 12, wherein the processor is further configured to, before reading the compressed neural network parameter from the memory:
obtain sample data;
perform training according to the sample data to obtain a neural network parameter;
compress the neural network parameter to obtain the compressed neural network parameter; and
write the compressed neural network parameter into the memory.

14. The device of claim 13, wherein the processor is further configured to:
compress the neural network parameter using a lossless compression algorithm to obtain the compressed neural network parameter.

15. The device of claim 13, wherein the processor is further configured to:
compress the neural network parameter using a lossy compression algorithm with a compression rate greater than a preset compression rate to obtain the compressed neural network parameter.

16. The device of claim 12, wherein:
the neural network includes a convolutional neural network; and
the processor is specifically configured to perform a convolution operation and a pooling operation on the target data according to a decompressed neural network parameter.

17. The device of claim 12, wherein the neural network parameter includes a weight and an offset of the neural network.

18. The device of claim 12, wherein the processor is further configured to read the target data from the memory before processing the target data according to the decompressed neural network parameter.

19. The device of claim 18, wherein the processor is further configured to write a result of processing the target data into the memory after processing the target data according to the decompressed neural network parameter.

20. An unmanned aerial vehicle comprising:
a frame including:
a plurality of vehicle arms each configured to carry a motor and a propeller, the propeller being configured to drive the unmanned aerial vehicle to fly under an action of the motor;
a memory; and
a processor connected to the memory via a communication bus and configured to:
read a compressed neural network parameter from the memory;
decompress the compressed neural network parameter to generate a decompressed neural network parameter; and
process target data to be processed according to the decompressed neural network parameter;
a gimbal; and
an image device connected to the frame via the gimbal.
